(19) United States
(12) Patent Application Publication
(10) Pub. No.: US 2018/0159446 A1
(43) Pub. Date: Jun. 7, 2018

(54) ELECTROSTATIC MICROGENERATOR AND METHOD FOR GENERATING ELECTRICAL ENERGY USING AN ELECTROSTATIC MICROGENERATOR

(71) Applicant: Guenter BECKMANN, Dachau (DE)

(72) Inventors: Enrico BISCHUR, Muenchen (DE); Norbert SCHWESINGER, Eching (DE); Sandy ZAEHRINGER, Dachau (DE)

(73) Assignee: Guenter BECKMANN, Dachau (DE)

(21) Appl. No.: 15/550,875

(22) PCT Filed: Feb. 13, 2016
(86) PCT No.: PCT/DE2016/100068

§ 371 Date: Aug. 14, 2017

(30) Foreign Application Priority Data
Feb. 13, 2015 (LU) 92654

(51) Int. Cl. H02N 1/08; H02N 2/18; H01G 7/02; H01H 13/28

(52) U.S. Cl. CPC H02N 1/08; H02N 2/181; B81B 3/0018; H01H 13/28; H01G 7/02

(57) ABSTRACT

An electrostatic microgenerator having electret films which are arranged above one another in a double layer and each have a metal layer arranged on one side thereof as an electrode. The films are embedded in a hermetically sealed casing in a loosely wound manner. Applying pressure to a first desired pressure surface, which is provided on the outside parallel to the capacitor plates formed in this manner, makes it possible to generate an electrical voltage by changing the distance between the capacitor plates.

### TECHNICAL FIELD

The invention relates to an electrostatic microgenerator having two polymer electret films which are arranged above one another in a double layer, as well as a pushbutton with an electrostatic microgenerator of this kind, as well as a manufacturing method thereof and a method for generating electrical energy.

### BACKGROUND ART

US 2004/0113526 A1 describes an electromechanical transducer with a multilayer structure which is capable of changing the thickness. Air can flow both in and out of the transducer element in the direction of the thickness of the transducer element. Air-permeable materials such as a permeable metal layer and a permeable material layer are used for this purpose. The material layer is permanently charged with an electrical charge.

### DESCRIPTION OF THE INVENTION

It is an object of the present invention to provide an electrostatic microgenerator, a pushbutton, a method for producing the same electrostatic microgenerator, and a method for generating electrical energy, which ensure stable conversion of mechanical energy into electrical energy.

According to the invention, the object is achieved by the subject of claims 1, 13, 14, and 15. Advantageous refinements emerge from the dependent claims.

A concept of the invention is to allow a fluid, in particular air, as an insulating medium to flow in and out parallel to a target pressure surface and parallel to spaced-apart capacitor plates, in which concept the distance between the capacitor plates is varied in order to generate electrical energy, therefore a tappable voltage. The fluid can be gaseous and thus compressible or liquid and thus not compressible. Both embodiments have advantages for the specific application. For this purpose, the electrostatic microgenerator has two polymer electret films, which are arranged above one another in a double layer and each has a metal layer arranged on one side thereof, as an electrode, wherein the metal layers each form capacitor plates and at least one fluid chamber variable in height between the capacitor plates, wherein a fluid in the at least one fluid chamber serves as an insulating medium, the electret films are embedded in a casing hermetically sealed for the fluid, and the electret films are wound in a planar and loose manner and are arranged in the hermetically sealed casing with a defined volume of fluid, wherein at least one compensation chamber for the fluid is provided in the casing, the fluid can be expelled from the at least one fluid chamber into at least one compensation chamber of the casing by applying pressure to a first target pressure surface, which is provided on the outside on the casing parallel to the capacitor plates, and a voltage can be generated by changing the distance between the capacitor plates, and the fluid, in particular air, and in particular exclusively, can be reintroduced and returned by applying pressure to a second target pressure surface, substantially in the direction perpendicular to the direction of the pressure application, from the at least one compensation chamber in the casing in a direction parallel to the arrangement of the capacitor plates into the at least one fluid chamber in order to widen the distance between them. Due to this specific construction, an interplay between introducing the fluid from the at least one compensation chamber into emptied fluid chambers and expelling the fluid from the fluid chambers arranged between the capacitor plates is simplified and efficient. Depending on the application, the internal volume of the casing cannot be reduced in the case of a liquid fluid and, in contrast, can preferably be reduced in the case of a gaseous fluid. It would also be possible to build up such a pressure, so that a phase change from the gaseous fluid to a liquid fluid takes place.

Because the fluid is limited in its volume as defined by the hermetically sealing casing, the casing is a highly effective means for efficiently utilizing a pressure force applied thereto and acting thereon for transformation into electrical energy. It is therefore provided to apply alternately a compressive force at two places on the casing in order to effect flow of the fluid in the one direction and the opposite direction. In this case, the casing is filled with only about half of the maximum possible fillable fluid in order to provide a compensation chamber for the second half.

In a first state, the fluid is filled in fluid chambers between capacitor plates and the casing on an opposite side is emptied accordingly. The casing is inflated on the opposite side, in particular opposite to the electret film, when a compressive force acts on the casing and the underlying electret film winding. The wound electret film with its metal electrodes is thus pressed against the fluid chambers. In order to again bring about the original state with filled fluid chambers between the capacitor plates, the section of the casing with the second target pressure surface with an underlying compensation chamber for the fluid, which chamber, depending on the embodiment, has one or no electret film, is then subjected to a compressive force so that the fluid, in particular air, flows between the capacitor plates and refills the fluid chambers.

An “electret film” is understood to be a film that is permanently electrostatically polarized. The electret film preferably has a thickness of 1 μm to about 100 μm, more preferably about 20 μm to about 50 μm. Thus, a stable electrostatic microgenerator is produced with a stable conversion of mechanical to electrical energy. The electrostatic microgenerator is constructed in a simplified manner so that it can be produced cost-effectively and wide application is possible.

In order to significantly increase the efficiency, the electret films, when viewed in cross section, to form a plurality of film capacitors in series with a variable distance between the capacitor plates, are wound in a planar manner to form a film winding, wherein in each case the sides of the electret film of the same polarity are arranged toward one another and the capacitor plates as electrodes of the same polarity are connected together to form a line. Thus, a significantly higher voltage is generated depending on the number of the series-connected film capacitors.

In a further preferred embodiment, it has been found to be advantageous that the metal layer, arranged on the electret film, and in particular the electret film are made substantially impermeable to the fluid, in particular to air. As a result, the efficiency is increased further, and due to the simple structure, an efficient production can be realized in a more feasible manner for an economical implementation.

According to an embodiment refining the invention and in order to further simplify the manufacturing process and to produce a high efficiency of the electrostatic microgenerator, the metal layer is arranged as a separate metal film on the polymer electret film. The efficiency is thus not impaired by a perforation of the electret film and/or the metal layer. According to an alternative preferred embodiment, the metal layer is formed as a metallization on the polymer electret film in a special production process.

According to a further particularly preferred embodiment, in order to produce the highest possible efficiency and to simplify the manufacturing process as well as the structure of the microgenerator, the electret film has the metal layer in a completely covering manner on the one side of the electret film.

According to an alternative preferred embodiment, the electret film has the metal layer substantially centrally on the one side with parallel free edge strips without a metal layer. The free parallel edge strips are preferably used further for elastic spacers, which are arranged between two layers of the electret film, in each case on the two free edge strips without a metal layer. This ensures that a space with fluid chambers is created for the fluid, in particular air, which space is compressible and, by virtue of the counterpressure of the fluid, again takes up its original space with the maximum large fluid chambers.

According to an alternative embodiment, the metal layer is formed on the electret film on one side on parallel edge strips with a free central strip without a metal layer.

According to an embodiment refining the invention, the electret films, arranged in a double layer, are arranged on one side in the casing and the at least one compensation chamber is arranged on an opposite side in the casing. Thus, simple windings of electret films with capacitor plates as electrodes can be produced.

According to an alternative embodiment, the electrostatic microgenerator comprises electret films, arranged in a double layer, with fluid chambers disposed therebetween as a mutually formed compensation chamber, in each case above the first and second target pressure surfaces. A compact microgenerator is provided in this way. In both embodiments, one casing is therefore provided as a double pocket, which is created by the two target pressure surfaces.

For this purpose, elastic spacers are arranged further preferably centrally between two layers of the electret film on the free central strip without a metal layer. This embodiment is an alternative embodiment to the above-described embodiment, which ensures that an original state is restored from an operating state with compressed electrode plates. In addition, the electrodes connected in series can be pressed together mutually, therefore alternately, with respect to the free central strip, so that the opposing capacitor plates are automatically brought apart by the inflow of the fluid. Thus, continuous energy generation is ensured, wherein the target pressure surfaces on the surface of the casing are alternately to be subjected to a compressive force.

According to an embodiment refining the invention, two target pressure surfaces are therefore arranged on the top side of the casing, which surfaces can be actuated alternately; in particular, a mechanism is provided which applies a compressive force alternately to both target pressure surfaces, proceeding from the action on a defined central button pressure surface.

It is preferred further that the electrostatic microgenerator has a spring mechanism, which counteracts a compression on the at least one target pressure surface and again brings apart capacitor plates, which were brought closer together, for electrical energy generation. This ensures that the electrostatic microgenerator time and again upon pressure steadily converts mechanical energy into electrical energy, namely, in both directions once when the capacitor plates are brought closer together and once when the capacitor plates are brought apart.

The object is also achieved by means of a pushbutton, with an above-described electrostatic microgenerator, wherein the pushbutton has a spring-loaded button element and a signal control for emitting an electronic signal upon actuation of the button element with the initiation of a pressure application to the target pressure surface of the microgenerator. A pushbutton of this kind has the advantage that mechanical energy is converted stably into electrical energy, it has a simple construction, and the pushbutton can be used both in a stationary and mobile manner, especially wherever a cabling effort is disadvantageous or complicated or undesirable.

In connection with a radio module, an autonomous pushbutton can thus be provided, which is independent of the limited energy storage capacity of a battery, by triggering and transmitting electrical signals when the button is actuated.

The object is also achieved by a method for producing an above-described electrostatic microgenerator with a polymer electret film by winding the electret film such that a fluid, in particular air, can flow in and out between layers of the electret film with electrodes as capacitor plates substantially perpendicular to the direction of the pressure application to a target pressure surface of the microgenerator and parallel thereto, and the wound electret film is hermetically sealed in a casing with a defined volume. In this case, preferably air as the gaseous fluid or dielectric oils as the liquid fluid can be enclosed in the casing with a defined volume, and the distance between the capacitor plates of the wound polymer electret film can be changed by varying the pressure applied to the casing. so that mechanical energy is converted stably and efficiently into electrical energy.

The object is also achieved by a method for generating electrical energy by means of an above-described electrostatic microgenerator in that a fluid, in particular air, as an insulating medium is expelled parallel to capacitor plates and perpendicular to a pressure application to a target pressure surface into a compensation chamber of a casing and, conversely, the fluid is introduced and returned to the fluid chamber from the storage space of the casing from the fluid chambers between capacitor plates to widen the distance between these parallel to the capacitor plates. By concentrating the flow direction parallel to the capacitor plates and perpendicular to the pressure direction, the stable conversion process from mechanical to electrical energy is produced. The method is simple in structure and can be realized cost-effectively.

It is understood that the features mentioned above and still to be explained below can be used not only in the particular combination indicated, but also in other combinations.

### BRIEF DESCRIPTION OF THE DRAWINGS

The invention will be explained in greater detail hereinbelow with the aid of exemplary embodiments with reference to drawings. In the drawing:

FIG. 1a shows a loosely wound structure of an electrostatic microgenerator without a casing;

FIG. 1b shows the wound electrostatic microgenerator according to FIG. 1 with an acting compressive force;

FIG. 2 shows a schematic arrangement of the electret films with a metal layer and their line connection;

FIG. 3a shows a schematic first embodiment of the electrostatic microgenerator in the relaxed state;

FIG. 3b shows the schematically illustrated microgenerator according to FIG. 3a with an acting compressive force;

FIG. 4a shows a second embodiment of the electrostatic microgenerator in the relaxed initial state;

FIG. 4b shows the second embodiment of the microgenerator according to FIG. 4a with a compressive force acting on a target pressure surface;

FIG. 5 shows a third embodiment in a schematic side view of the electrostatic microgenerator;

FIG. 5a shows a schematic view of the third embodiment according to FIG. 5 with an acting compressive force as viewed in cross section on the left side;

FIG. 5b shows a schematic cross section of the third embodiment according to FIG. 5 with the compressive force acting on the right side;

FIG. 6 shows a fourth embodiment of the electrostatic microgenerator;

FIG. 6a shows a cross-sectional view schematically with a compressive force acting on the left side according to the embodiment in FIG. 6;

FIG. 6b shows a schematic view of an embodiment according to FIG. 6 with the compressive force acting on the right side;

FIG. 7 shows a schematic view of a pushbutton of the invention;

FIG. 8 shows the process sequence of a manufacturing process of the invention for an electrostatic microgenerator; and

FIG. 9 shows the process steps using a flowchart for generating electrical energy by means of a microgenerator.

### BEST MODE FOR CARRYING OUT THE INVENTION

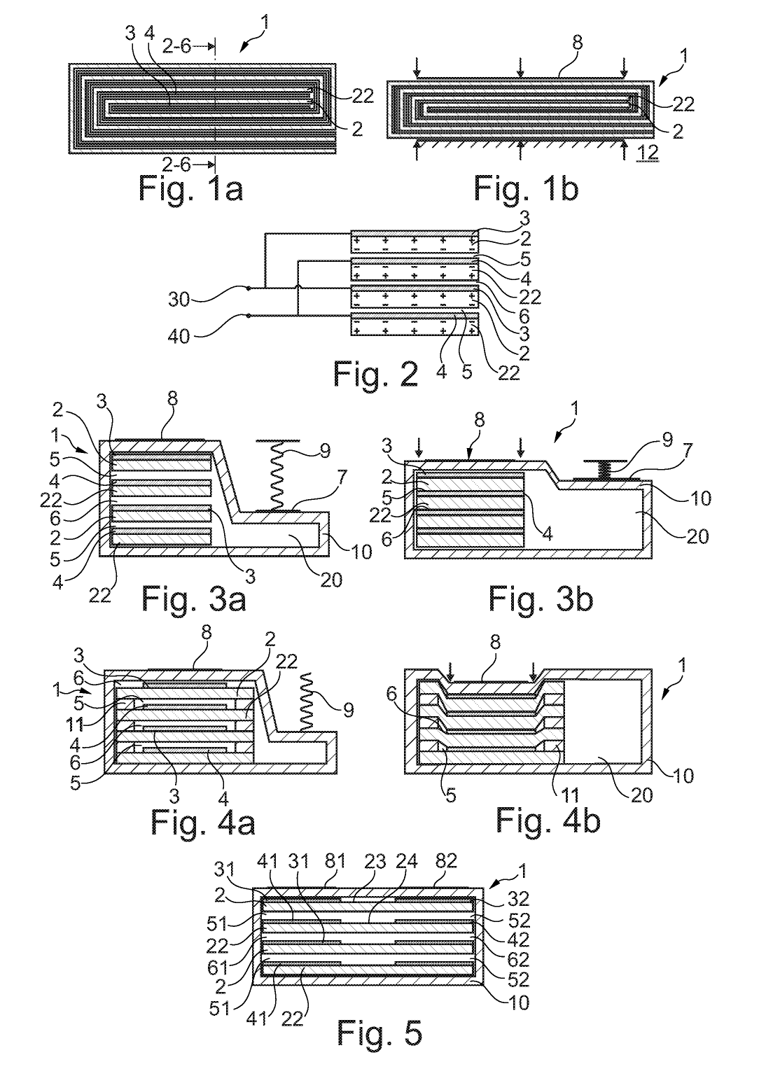

FIG. 1 shows schematically an electrostatic microgenerator 1 of the invention with two polymer electret films 2, 22 arranged in a double layer. An electret film is defined as a permanently electrostatically charged film. On one side, a metal layer is arranged as an electrode on electret film 2, 22. Electret films 2, 22 in a double layer with two metallic electrodes form capacitor plates 3, 4 to form at least one film capacitor. As shown in FIG. 1a, polymer electret films 2, 22 arranged in a double layer are preferably loosely wound repeatedly in a planar manner to form a film winding. FIG. 1a shows a triple winding. It is understood that the winding may be wound more or less than three times. In the case of multiple windings, therefore, this results in a plurality of film capacitors arranged in series above on another. In microgenerator 1, a fluid, preferably air, as an insulating medium is enclosed between the individual polymer electret films 2, 22 in fluid chambers 5, 6. Fluid chambers 5, 6 are formed by capacitor plates 3, 4 as well as by the surface sides of electret films 2, 22 without a metal layer. A variable distance of capacitor plates 3, 4 can be produced if an external compressive force acts on microgenerator 1 as shown in FIG. 1b. The metal layer is preferably arranged in each case on one side directly on electret film 2, 22 without an intermediate gap, so that there is no gap between polymer electret film 2, 22 and the metal layer, which is either formed as a separate metal film or is formed as a metallization arranged on polymer electret film 2, 22. Thus, each electret film 2, 22 is a carrier of a capacitor plate 3, 4.

FIG. 1b shows the same schematic cross-sectional view as FIG. 1a, with the difference that pressure is applied to electrostatic microgenerator 1 from FIG. 1a in a planar manner to target pressure surface 8 from one side against a bearing surface 12, such that the embedded fluid between the double layers of polymer electret film 2, 22 is expelled from fluid chambers 5, 6. Both in the expelling process and in the process that introduces the fluid back into fluid chamber 5, 6 between capacitor plates 3, 4, a tappable voltage with an effective current intensity is produced, which is detectable in particular as an electrical signal after rectification and can be supplied to an electrical consumer.

FIG. 2-6 or 3b-6b show schematic sectional views of FIGS. 1a and 1b with a hermetically sealed casing 10.

FIG. 2 shows a schematic enlarged sectional view with two electret films 2, 22, arranged in a double layer above one another, for the formation of electrostatic microgenerator 1. Electret films 2, 22 need not necessarily initially have charges. Piezoelectric electret films in particular can also be used without initial polarization. In FIG. 2, electret film 2, 22 is formed, for example, with permanent polarizations. In the uppermost, first electret film 2, the top layer thereof is positively charged with a metal layer as capacitor plate 3. The bottom side of electret film 2 has a negative charge without a metal layer. In the relaxed state, a fluid chamber 5 with a variable height is provided for the fluid, here preferably air, following the capacitor structure perpendicular to capacitor plate 3. The height of fluid chamber 5, 6 can be varied as a minimum height between a direct contact of the bottom side of electret film 2 with second capacitor plate 4 and as a maximum height with a defined distance from the bottom side of electret film 2 and capacitor plate 4. In the configuration perpendicular to the capacitor, the metal layer of capacitor plate 4 is charged with a negative polarization and connected to second electret film 22. In the case of second electret film 22, conversely, the top side is negatively charged and the bottom side is positively charged. This is followed in the structure by a further fluid chamber 6 with a variable height and, again, by the same arrangement, as previously described, of a first electret film 2 with a first positively charged electrode as capacitor plate 3 and after a further fluid chamber 5, and thereupon a further second electret film 22 with a negatively charged second electrode as capacitor plate 4. As shown in FIG. 2, the sides of electret film 2, 22 of the same polarity are arranged toward one another, and the capacitor plates of the same polarity are connected together to form a line. The two capacitor plates 4 are thus connected to one another to form a line 40 with a negative polarization, and the two positively charged capacitor plates 3, which form the first electrode, are connected to the positive line 30 with a positive polarization.

FIG. 3a shows a schematic cross-sectional view of electrostatic microgenerator 1, in a preferred embodiment, inserted into a hermetically sealed casing 10 which has a defined fluid volume, in particular a fluid volume, in a relaxed state. As seen in cross section, the film winding with electret films 2, 22 is arranged on the left side, whereas on the right side casing 10 is reduced to a defined minimum. An essential feature of microgenerator 1 of the invention is therefore a “double pocket” with electrodes 3, 4 and electret films (2, 22) formed as a dielectric and casing 10, which would have a fluid volume twice as large in a state fictively filled with fluid, as used according to the invention. Because only half of the actually possible fluid volume is located in hermetically sealed casing 10, the fluid must escape from the fluid-filled region into an unfilled compensation chamber when pressure is applied. A target pressure surface 8 is arranged on casing 10 above the two electret films 2, 22 wound in double layers. Shown lying opposite in the cross section on the right in FIG. 3a, a relaxed spring 9 is arranged which presses against a counterpressure surface 7 of casing 20. Spring 9 serves as a mechanism which counteracts target pressure surface 8.

FIG. 3b shows electrostatic microgenerator 1 in a state with a maximum pressure effect on target pressure surface 8, so that fluid chambers 5, 6 with the variable height contact the negatively charged metallic layer of second electret film 22 to form a minimum space with a minimum height with substantially direct contact between the negatively charged bottom side of electret film 2. The fluid as the insulating medium has been expelled from the film winding and now defines a hermetically sealed compensation chamber 20 on the right side in casing 10. During the process of pressure application to target pressure surface 8 according to FIG. 3a to FIG. 3b, a change in capacitance occurs due to the change in the distance between capacitor plates 3, 4. This change in capacitance leads to the desired arising voltage as does a pressure application to counterpressure surface 7 in the opposite direction. By means of spring 9, the fluid present is pumped again from compensation chamber 20 into fluid chambers 5 and 6, so that electret films 2, 22 with the two electrodes 3, 4 are brought apart to form a state according to FIG. 3a.

FIG. 4a shows a second specific embodiment of electrostatic microgenerator 1 as seen in cross section. In the case of this electrostatic microgenerator 1, metal layers 3, 4 are each arranged centrally on electret film 2, 22, elastic spacers 11 preferably made of plastic being arranged on parallel edge strips without a metal layer. Target pressure surface 8 is likewise located directly above the metal layers of capacitor plates 3, 4 and also not on the parallel edge strips in contrast to FIGS. 3a and 3b. Due to elastic spacers 11, fluid chambers 5 and 6 are predefined, so that the fluid, which has been expelled from fluid chambers 5, 6 by the action of the compressive force on target pressure surface 8, re-enters more easily. For this purpose, the fluid volume is defined by hermetically sealed casing 10.

FIG. 4b shows an electrostatic microgenerator 1 in the loaded state with a maximum applied compressive force on target pressure surface 8. Compensation chamber 20, arranged on the right side in FIG. 4b, is filled to a maximum with the fluid volume from the minimally reduced fluid chambers 5, 6. As described for FIGS. 3a and 3b, compensation chamber 20 is again emptied by a mechanism or equivalent mechanism, and fluid chambers 5, 6 are again enlarged by means of the fluid volume.

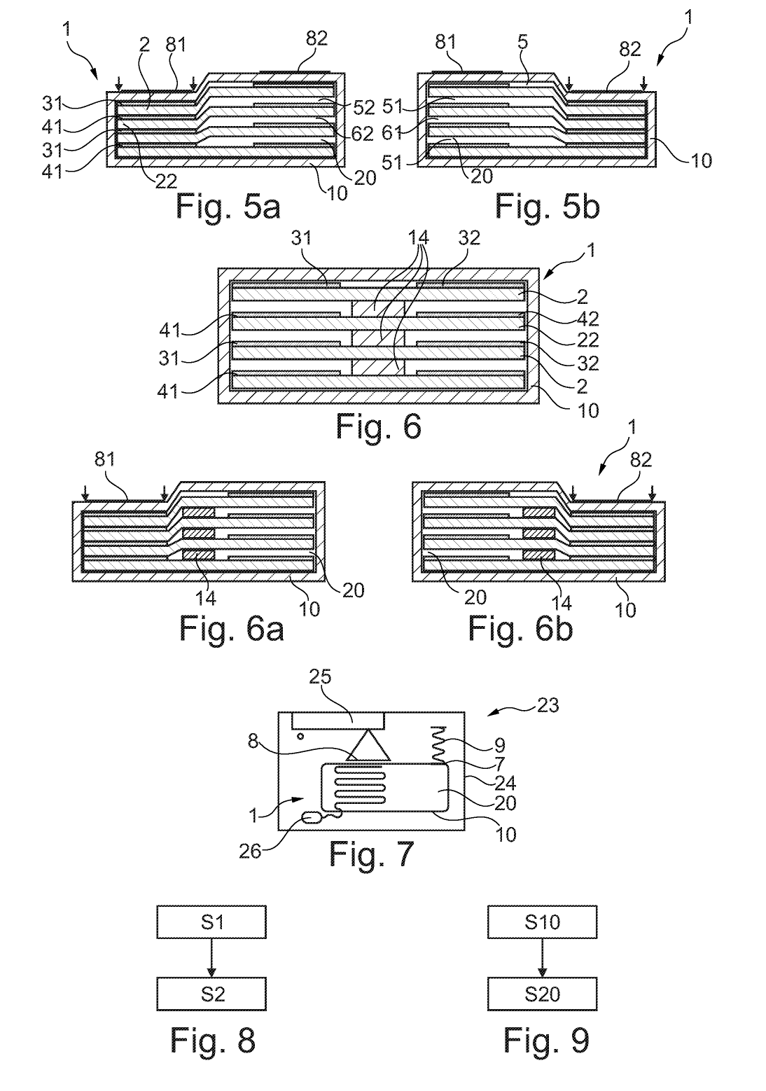

FIGS. 5, 5a, and 5b show a third embodiment of electrostatic microgenerator 1. In this particular embodiment, the metal layers are arranged parallel on both sides on the top side of an electret film 2, 22, a free strip 23, 24 without a metal layer being arranged centrally. This embodiment has two target pressure surfaces 81, 82, which are arranged in parallel above the metal layers. A target pressure surface is therefore also not provided at the center, where no metal layers are located.

FIG. 5 shows the above-described film winding in the relaxed, unloaded state. All fluid chambers 51, 52, 61, 62 have substantially the same fluid volume between capacitor plates 3, 4 and thus the same size and height.

FIG. 5a shows a left-sided pressure load in the schematic cross-sectional view of FIG. 5, so that fluid chambers 51, 52, 61, 62 from FIG. 5 are compressed to a minimum volume with a minimum height and the right-sided volume 52, 62 is filled maximally with fluid with at least one compensation chamber 20. All fluid chambers 51, 61 are emptied to the extent that electrode 31 thus touches hermetic casing 10 from the inside and the bottom side of second electret film 22, and the left-sided negative electrode 41 contacts the bottom side of first electret film 2.

FIG. 5b shows how target pressure surface 82 on the right side subsequently acts maximally with a compressive force on casing 10, so that a maximum capacitance change is produced on the right side and the opposite direction also on the left side, and fluid in fluid chambers 5, 51 is pressed parallel to capacitor plates 31, 41 and in the direction perpendicular to the pressure application, from fluid chambers 52, 62 into the previously closed fluid chambers 51, 61 and these form compensation chamber 20. In this embodiment, therefore, a substantially identical electrical characteristic is produced with respect to voltage and current intensity with each left-sided and right-sided pressure application.

FIGS. 6, 6a, and 6b show a further improved embodiment of FIG. 5. In this embodiment, spacers 14 are arranged centrally between electret films 2, 22. As described in FIGS. 4a and 4b, spacers 14 are used to return more easily to relaxed states after a compressive force effect on target pressure surface 81 or 82. In FIG. 6a, compensation chamber 20 is arranged for a start on the right side, and, in the illustration of FIG. 6b, it travels to the left side of casing 10 formed as a double pocket.

FIG. 7 shows schematically in cross section a pushbutton 23 of the invention with a button element 25, a housing 24, and a previously described electrostatic microgenerator 1 of the invention. When pushbutton element 25 is actuated as a central button pressure surface, a compressive force is exerted on target pressure surface 8 of electrostatic microgenerator 1 so that an electrical energy and voltage are generated. Spring 9 arranged on the right side takes the microgenerator back into a relaxed state, so that pushbutton 23 can be actuated again. Electrostatic microgenerator 1 is coupled to a signal control 26 which, upon actuation of pushbutton element 25, transmits the converted electric energy as an electrical signal, for example, to a radio module, so that the signal of pushbutton 23 is processed in an overall electrical application.

FIG. 8 shows the two method steps for producing an electrostatic microgenerator 1 of the invention. In a first method step S1, a polymer electret film 2, 22 is wound in a loose and planar manner in a double layer with an arranged metal layer, and in a second step S2 the wound electret film 2, 22 is hermetically sealed in a casing 10 with a defined fluid volume.

FIG. 9 shows the two method steps for generating electrical energy by means of an electrostatic microgenerator 1, as it is described above. In a first step (step S10), a fluid, in this case particularly preferably air, as an insulating medium is expelled parallel to capacitor plates 3, 4, which are arranged as metal layers on an electret film 2, 22 and perpendicular to a pressure application to target pressure surface 8, from fluid chambers 5, 6 into a compensation chamber 20, in particular a storage space of casing 10, and vice versa

In step S20, the fluid is again introduced out of compensation chamber 20 from the casing and therefore returned to fluid chambers 5, 6 between capacitor plates 3, 4, parallel to the widening of the distance between these.

By the parallel introduction of fluid and conversely the expulsion, a very high efficiency is therefore achieved in a stable conversion process of mechanical to electrical energy. Thus, the electrostatic microgenerator can be produced much more simply and thus more cost-effectively, wherein a wide selection of materials is also possible. Any known electret material, such as, for example, polytetrafluoroethylene (PTFE), polyethylene terephthalate (PET), polyvinyl chloride (PVC), etc., or in particular

polyvinylidene fluoride (PVDF), can be used as the film.

Although exemplary embodiments were explained in the present description, it should be pointed out that a large number of modifications are possible. In addition, it should be pointed out that the exemplary embodiments are merely examples that should not in any way restrict the scope of protection, the application, and the structure. Rather, a guide for the implementation of at least one exemplary embodiment is provided to the skilled artisan by the foregoing description, whereby various changes can be made, in particular with regard to the function and arrangement of the described components, without leaving the scope of protection, as it emerges from the claims and these equivalent feature combinations.

1. An electrostatic microgenerator having two polymer electret films, which are arranged above one another in a double layer and each has a metal layer arranged on one side thereof, as an electrode, wherein the metal layers each form capacitor plates, and at least one fluid chamber variable in height is formed between the capacitor plates and a fluid in the at least one fluid chamber serves as an insulating medium, the electret films are embedded in the casing, hermetically sealed for the fluid, the electret films are wound in a planar and loose manner and are arranged in the hermetically sealed casing having a defined volume of the fluid, wherein a compensation chamber for the fluid is provided in the casing, wherein the fluid can be expelled from the at least one fluid chamber into at least one compensation chamber of the casing by applying pressure to a first target pressure surface, which is provided on the outside on the casing parallel to the capacitor plates, and a voltage can be generated by changing the distance between the capacitor plates and the fluid can be reintroduced and returned by applying pressure to a second target pressure surface, substantially in the direction perpendicular to the direction of the pressure application, from the at least one compensation chamber of the casing in a direction parallel to the arrangement of the capacitor plates into the fluid chamber in order to widen the distance between these parallel to the capacitor plates.

2. The electrostatic microgenerator according to claim 1, wherein the electret films, when viewed in cross section, to form a plurality of film capacitors in series with a variable distance between the capacitor plates, are wound in a planar manner to form a film winding, wherein in each case the sides of the electret film of the same polarity are arranged toward one another and the capacitor plates as electrodes of the same polarity are connected together to form a line.

3. The electrostatic microgenerator according to claim 1, wherein the metal layer and in particular the electret film are made substantially impermeable to the fluid, in particular to air.

4. The electrostatic microgenerator according to claim 1, wherein the metal layer is arranged as a separate metal film on the polymer electret film or in particular the metal layer is formed as a metallization on the polymer electret film.

5. The electrostatic microgenerator according to claim 1, wherein the electret film has the metal layer in a completely covering manner on a top side.

6. The electrostatic microgenerator according to claim 1, wherein the electret film has the metal layer substantially centrally on a top side with parallel free edge strips without the metal layer, wherein elastic spacers are each arranged between two layers of the electret film, in each case on the two free edge strips without the metal layer.

7. The electrostatic microgenerator according to claim 1, wherein the metal layer is formed on the electret film on one side on parallel edge strips with a free central strip without a metal layer.

8. The electrostatic microgenerator according to claim 7, wherein elastic spacers are arranged centrally between two layers of the electret film on a free central strip without a metal layer.

9. The electrostatic microgenerator according to claim 1, wherein the electret films, arranged in a double layer, are arranged on one side in the casing and the at least one compensation chamber is arranged on an opposite side in the casing.

10. The electrostatic microgenerator according to claim 1, wherein the electret films, arranged in a double layer, with their fluid chambers as a mutual compensation chamber are formed in each case above the first and second target pressure surface.

11. The electrostatic microgenerator according to claim 8, wherein two target pressure surfaces are arranged on the top side of the casing, which surfaces can be actuated alternately, in particular a mechanism being provided, which applies compressive force alternately to both target pressure surfaces, proceeding from the action on a defined central button pressure surface.

12. The electrostatic microgenerator according to claim 1, wherein the electrostatic microgenerator has a spring mechanism, which counteracts a compression on the at least one target pressure surface and again brings apart capacitor plates, which were brought closer together, for electrical energy generation.

13. A pushbutton comprising an electrostatic microgenerator, according to claim 9, a spring-loaded button element, and a signal control for emitting an electronic signal upon actuation of the button element with the initiation of a pressure application to the target pressure surface of the microgenerator.

14. A method for producing an electrostatic microgenerator according to claim 1 with a polymer electret film, wherein the electret film is wound such that a fluid can flow in and out between layers of the electret film and electrodes as capacitor plates substantially perpendicular to the direction of the pressure application to a target pressure surface of the microgenerator and parallel thereto and the wound electret film is hermetically sealed in a casing with a defined fluid volume.

15. A method for generating electrical energy by means of an electrostatic microgenerator according to claim 1, wherein a fluid, in particular air, as an insulating medium is expelled parallel to capacitor plates and perpendicular to a pressure application to a target pressure surface into a compensation chamber of a casing and, conversely, the fluid is introduced and returned from the compensation chamber of the casing between capacitor plates to widen the distance between these parallel to the capacitor plates.
